(19) United States
(12) Patent Application Publication
(10) Pub. No.: US 2025/0015715 A1
(43) Pub. Date: Jan. 9, 2025

(54) SWITCHED-CAPACITOR BATTERY MANAGEMENT POWER SUPPLY PROVIDING POWER FROM PORTIONS OF A MULTI-CELL BATTERY

(71) Applicant: CIRRUS LOGIC INTERNATIONAL SEMICONDUCTOR LTD., Edinburgh (GB)

(72) Inventor: John L. Melanson, Austin, TX (US)

(21) Appl. No.: 18/347,458

(22) Filed: Jul. 5, 2023

(51) Int. Cl. H02M 3/07; G01R 31/396; H02J 7/00; H02J 7/34

(52) U.S. Cl. CPC H02M 3/07; G01R 31/396; H02J 7/0047; H02J 7/345

(57) ABSTRACT

A circuit for powering a battery monitor in devices powered by a multi-cell battery, provides efficient use of energy in standby operating modes of battery-powered devices. The circuit includes a switched-capacitor network having at least two capacitors and at least two corresponding first switches. The capacitors have first terminals intermittently coupled in alternation to first terminals of corresponding cells or groups of cells of the multi-cell battery and second terminals of the corresponding cells or groups of cells of the multi-cell battery by the first switches according to a first clock signal. The switched-capacitor network also includes at least one second switch that intermittently couples second terminals of the at least two capacitors to an output node according to the first clock signal. The output node is configured to supply power to the battery monitor. The circuit also includes a clocking circuit for generating the first clock signal.

### BACKGROUND

### 1. Field of Disclosure

The field of representative embodiments of this disclosure relates to battery-operated circuits, systems and their methods of operation, and in particular to a switched-capacitor technique for powering a battery management integrated circuit (IC) from a cell or groups of cells of a multi-cell battery.

### 2. Background

In battery-powered portable devices, such as mobile telephones, tablets, notebook computers, along with other battery-operated devices, battery monitoring circuits, and in some case, other standby circuitry must continue to receive operating voltage. Although the current drain of such circuitry is generally quite low compared to operating current when the devices are fully active, the battery monitoring and/or standby circuit operating current may be drawn for a substantial time, hours/weeks, which can lead to substantial battery discharge, sometimes to a level at which the battery must be re-charged before operating the device.

Typical powering of battery monitoring and other standby circuits is performed using a low-dropout (LDO) regulator that drops the full battery voltage, e.g., 12V to a lower voltage, such as 1.8V to provide the operating power supply rail, at least in a low-power/standby operating mode. However, such a scheme uses battery energy inefficiently, for example, the above-described scheme wastes energy in proportion to 10.2V/12V, which is 85% wasted energy or 15% efficient.

Therefore, it would be advantageous to provide a circuit to power battery monitoring circuits and other standby circuitry with a more efficient use of battery energy.

### SUMMARY

The objective of providing a circuit to power battery monitoring circuits and other standby circuitry with a more efficient use of battery energy is accomplished in a circuit for powering a battery monitoring circuit and its method of operation.

The circuit is a circuit for providing power to a battery monitor that monitors a condition of a multi-cell battery. The circuit includes a switched-capacitor network having at least two capacitors and at least two corresponding first switches. The capacitors have first terminals intermittently coupled in alternation to first terminals of corresponding cells or groups of cells of the multi-cell battery and second terminals of the corresponding cells or groups of cells of the multi-cell battery by the first switches according to a first clock signal. The switched-capacitor network also includes at least one second switch that intermittently couples second terminals of the at least two capacitors to an output node according to the first clock signal. The output node is configured to supply power to the battery monitor. The circuit also includes a clocking circuit for generating the first clock signal.

The summary above is provided for brief explanation and does not restrict the scope of the claims. The description below sets forth example embodiments according to this disclosure. Further embodiments and implementations will be apparent to those having ordinary skill in the art. Persons having ordinary skill in the art will recognize that various equivalent techniques may be applied in lieu of, or in conjunction with, the embodiments discussed below, and all such equivalents are encompassed by the present disclosure.

### BRIEF DESCRIPTION OF THE DRAWINGS

FIG. 1 is a block diagram illustrating an example system 10, in accordance with an embodiment of the disclosure.

FIGS. 2A-2C are schematic diagrams illustrating example switched-capacitor battery management power supply circuits 20A-20C, respectively, that may be used to implement battery management power supply circuits 20 in example system 10 of FIG. 1, in accordance with various embodiments of the disclosure.

FIG. 3 is a signal waveform diagram 30 illustrating example signals within example switched-capacitor battery management power supply circuit 20C, in accordance with an embodiment of the disclosure.

FIGS. 4A-4B are schematic diagrams illustrating example switched-capacitor battery management power supply circuits 20D and 20E, respectively, that may be used to implement battery management power supply circuits 20 in example system 10 of FIG. 1, in accordance with other embodiments of the disclosure.

FIG. 5 is a schematic diagram illustrating an example switched-capacitor battery management power supply circuit 20F, that may be used to implement battery management power supply circuit 20 in example system 10 of FIG. 1, in accordance with another embodiment of the disclosure.

FIG. 6 is a block diagram illustrating another example system 50, in accordance with an embodiment of the disclosure.

FIG. 7 is a block diagram illustrating another example system 60, in accordance with an embodiment of the disclosure.

### DETAILED DESCRIPTION OF ILLUSTRATIVE EMBODIMENT

The present disclosure encompasses circuits and integrated circuits and their methods of operation. The circuits provide power to battery monitoring circuitry and other standby circuitry in battery operated devices, such as mobile telephones, tablets, notebook computers, along with other battery-operated devices. A switched-capacitor network, clocked by a clocking circuit, and including at least two capacitors and at least two corresponding first switches, couples first terminals in alternation to first terminals of corresponding cells or groups of cells of the multi-cell battery and second terminals of the corresponding cells or groups of cells of the multi-cell battery. The switched-capacitor network further includes at least one second switch that intermittently couples second terminals of the at least two capacitors to at least one output node that is configured to supply power to the battery monitor.

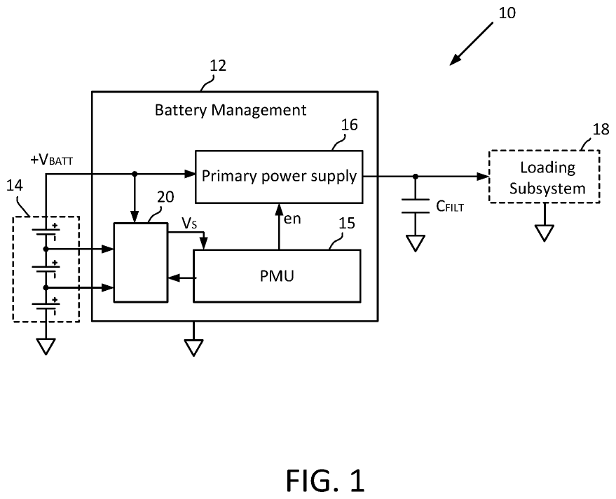

Referring now to FIG. 1, a block diagram illustrating an example system 10 is shown, in accordance with an embodiment of the disclosure. Example system 10 is a power supply system for providing power to a loading subsystem 18 of an electronic device from a multi-cell battery 14. A battery management block 12 which may be in the form of a battery management IC, or which may be integrated along with other circuits in an IC, includes a primary power supply 16, that supplies power to loading subsystem 18 when example system 10 is in an operating mode. A power management unit (PMU) 15 within battery management block 12 controls whether primary power supply 16 is operational, according to a control signal en. PMU 15 includes battery monitoring circuitry that may, for example, evaluate a health of battery 14, a lifetime of battery 14, and/or a charge level of battery 14. Portions of PMU 15 are generally operable when example system 10 is not in an operating mode, i.e., when example system 10 is in a standby mode or when example system 10 is “off.” In accordance with embodiments of the disclosure described herein, a switched-capacitor battery management power supply circuit 20 provides operating current/power from battery 14 via a supply voltage V_{S}, provided as an output from switched-capacitor battery management power supply circuit 20. Supply voltage V_{S} may supply operating current to PMU 15 under all conditions, or only when example system 10 is in standby mode.

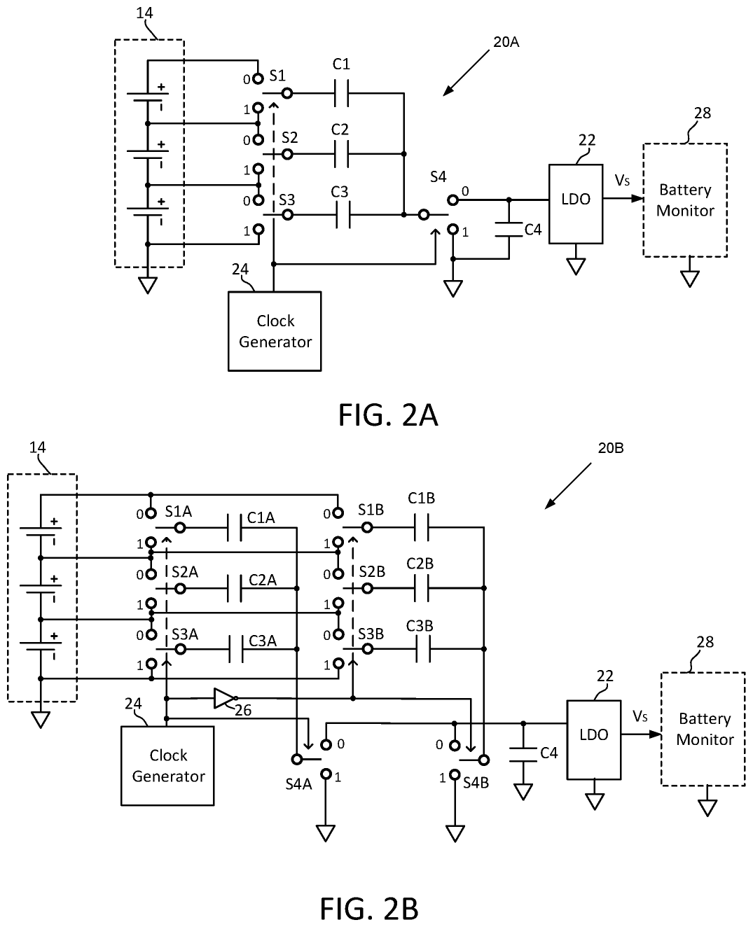

Referring now to FIG. 2A, a schematic diagram illustrating an example switched-capacitor battery management power supply circuit 20A that may be used to implement switched-capacitor battery management power supply circuit 20 of FIG. 1 is shown, in accordance with an embodiment of the disclosure. Example switched-capacitor battery management power supply circuit 20A includes a plurality of switched-capacitor resistors, implemented by switches S1, S2, and S3 and capacitors C1, C2, and C3 that draw power from individual cells of multi-cell battery 14, for supplying power via supply voltage V_{S} that is generated by a low drop-out (LDO) circuit 22, which may be a voltage regulator, or in some cases, a transistor configured as an emitter-follower. A clock generator 24 operates switches S1-S3 and another switch S4 that provides the output of the switched-capacitor network formed by the switching network of switches S1, S2, S3 and S4 and capacitors C1, C2, and C3. The output of clock generator 24 is illustrated for simplification as a single signal, e.g., a square-wave clock, but additional non-overlap circuitry may be used to provide two separate phases that operate individual transistors forming switches S1, S2, S3 and S4. The phase of the clock signal as corresponding to the action of switches S1, S2, S3 and S4 are indicated by “0” and “1” adjacent to the poles of switches S1, S2, S3 and S4. In phase “0”, switches S1, S2, S3 couple the positive terminals of their corresponding cells of multi-cell battery 14 to first terminals of capacitors C1, C2, and C3, respectively, and switch S4 couples the second terminals of capacitors C1, C2, and C3 to a capacitor C4, so that capacitors C1, C2, and C3 will transfer charge to capacitor C4 based on the difference in voltage between the corresponding terminal of multi-cell battery 14 and the voltage on capacitor C4. In phase “1”, switches S1, S2, S3 couple the negative terminals of their corresponding cells of multi-cell battery to first terminals of capacitors C1, C2, and C3, respectively, and switch S4 couples their second terminals to ground, setting the individual potentials across capacitors C1, C2, and C3 to reference their initial voltage in the next cycle to the negative terminals of their corresponding cells of multi-cell battery 14. The result is an equal removal of charge from each of the cells and transfer of the charge to capacitor C4 with a potential equal to the individual cell voltage, which is then provided to LDO 22 to generate supply voltage V_{S}, which powers a battery monitor 28.

Referring now to FIG. 2B, a schematic diagram illustrating an example switched-capacitor battery management power supply circuit 20B that may be used to implement switched-capacitor battery management power supply circuit 20 of FIG. 1 is shown, in accordance with another embodiment of the disclosure. Example switched-capacitor battery management power supply circuit 20B is similar in structure and operation to example switched-capacitor battery management power supply circuit 20A of FIG. 2A, so only differences between them are described in further detail below. Switches S1A, S2A, and S3A and capacitors C1A, C2A, and C3A implement the same first switched-capacitor network as S1, S2, and S3 and capacitors C1, C2, and C3 in example switched-capacitor battery management power supply circuit 20A of FIG. 2A. A second switched-capacitor network is formed by switches S1B, S2B and S3B and capacitors C1B, C2B, and C3B and is operated by a clock signal that is complementary to the clock that operates the first switched-capacitor network, as inverted by an inverter 26. Switches S4A and S4B alternatively couple the first or second switched-capacitor networks to capacitor C4 and the other switched-capacitor network to ground, so that charge is transferred from the cells of multi-cell battery at each half-cycle, reducing the required capacitance of capacitor C4 by a factor of two.

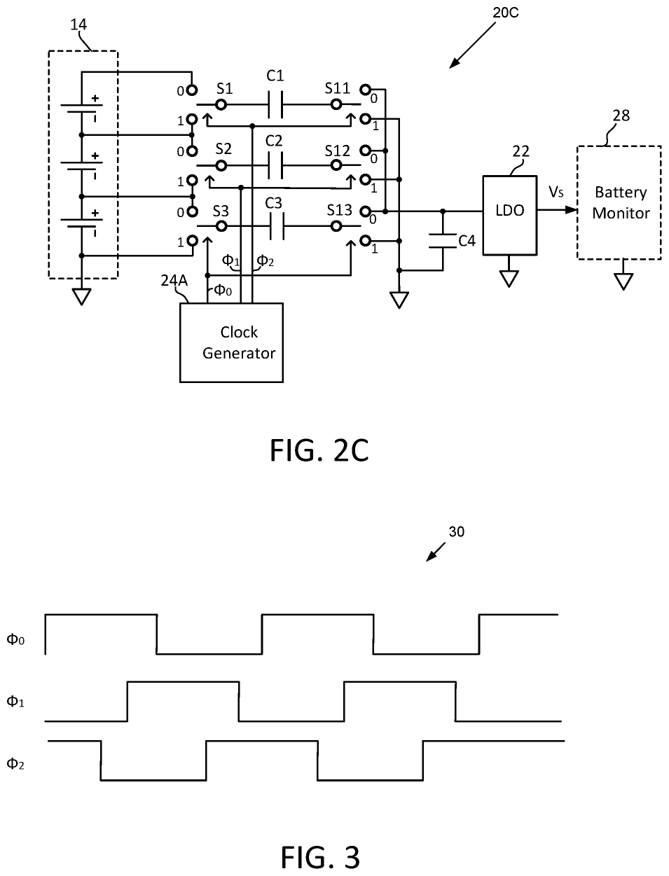

Referring now to FIG. 2C, a schematic diagram illustrating an example switched-capacitor battery management power supply circuit 20C that may be used to implement switched-capacitor battery management power supply circuit 20 of FIG. 1 is shown, in accordance with another embodiment of the disclosure. Example switched-capacitor battery management power supply circuit 20C is similar in structure and operation to example switched-capacitor battery management power supply circuit 20A of FIG. 2A, so only differences between them are described in further detail below. In example switched-capacitor battery management power supply circuit 20C, a second network of switches S11, S12, and S13 couple the second terminals of capacitors C1, C2, and C3 alternatively between capacitor C4 and ground, so that rather than a common connection between the second terminals of capacitors C1, C2, and C3, as in example switched-capacitor battery management power supply circuit 20A of FIG. 2A, but permits separation of the individual switched-capacitor resistors implemented by switches S1, S2, S3, S11, S12, and S13 and capacitors C1, C2, and C3 and permits their operation by separate and overlapping phases Φ₀, Φ₁, and Φ₂, of a clock generated by a clock generator 24A. Referring additionally to FIG. 3, a signal waveform diagram 30 illustrating example signals within example switched-capacitor battery management power supply circuit 20C is shown, in accordance with an embodiment of the disclosure. Clock phases Φ₀, Φ₁, and Φ₂, are illustrated as evenly spaced phases that further permit reduction of the capacitance of capacitor C4.

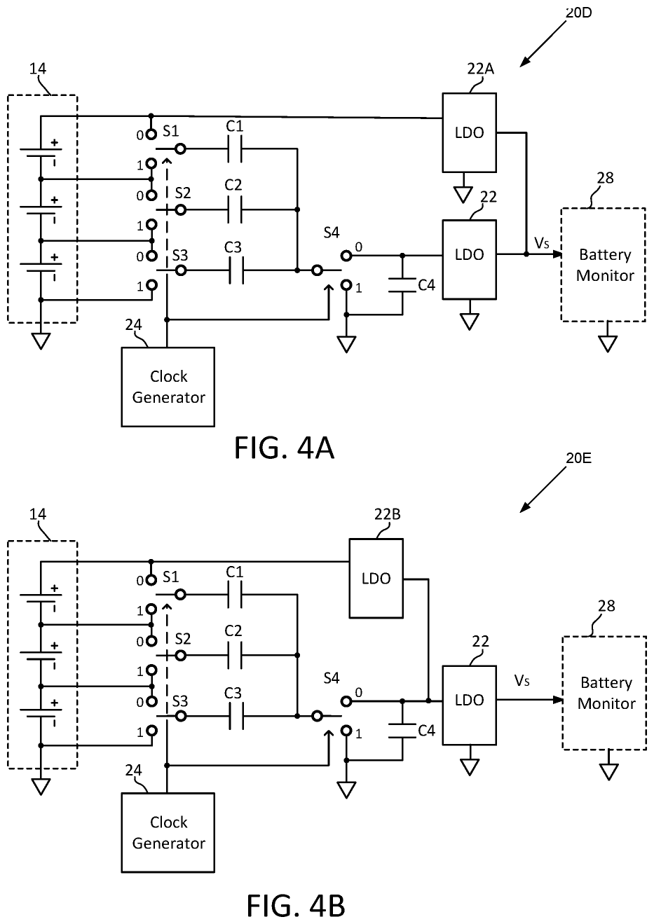

Referring now to FIG. 4A, a schematic diagram illustrating another example switched-capacitor battery management power supply circuit 20D that may be used to implement battery management power supply circuit 20 in example system 10 of FIG. 1, in accordance with another embodiment of the disclosure. Example switched-capacitor battery management power supply circuit 20D is similar in structure and operation to example switched-capacitor battery management power supply circuit 20A of FIG. 2A, so only differences between them are described in further detail below. Rather than supplying all of the power to PMU 15 in example system 10, of FIG. 1, a second LDO 22A may be connected in parallel with LDO 22 to supply power from the entire cell stack of multi-cell battery 14 directly during conditions in which the impedance of the switched-capacitor power supply circuit available at the output of LDO 22 is too high to source enough current, for example in full-power operating mode, or transitions. As long as those demands are infrequent, the improved efficiency provided by the remainder of switched-capacitor battery management power supply circuit 20D will still be significant, leading to a net increase in energy available from multi-cell battery 14.

Referring now to FIG. 4B, a schematic diagram illustrating another example switched-capacitor battery management power supply circuit 20E that may be used to implement battery management power supply circuit 20 in example system 10 of FIG. 1, in accordance with another embodiment of the disclosure. Example switched-capacitor battery management power supply circuit 20E is similar in structure and operation to example switched-capacitor battery management power supply circuit 20D of FIG. 4A, so only differences between them are described in further detail below. In capacitor battery management power supply circuit 20E, an LDO 22B is connected directly to capacitor C4, rather than the output of LDO 22, which may be useful to maintain the voltage across capacitor C4 under the above-described high load conditions.

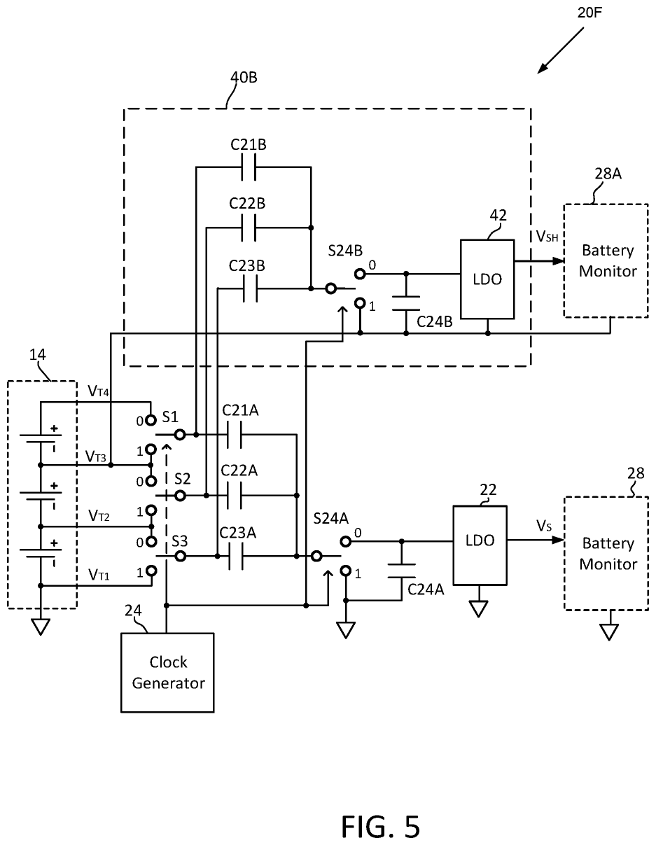

Referring now to FIG. 5, a schematic diagram illustrating another example switched-capacitor battery management power supply circuit 20F, that may be used to implement battery management power supply circuit 20 in example system 10 of FIG. 1, in accordance with another embodiment of the disclosure. Example switched-capacitor battery management power supply circuit 20F is similar in structure and operation to example switched-capacitor battery management power supply circuit 20A of FIG. 2A, so only differences between them are described in further detail below. In example switched-capacitor battery management power supply circuit 20F, an additional switched-capacitor power circuit 40B is included that shares switches S1-S3 to generate a separate power supply current for generating an output voltage V_{SH} to supply power to another battery monitor 28A. Switches S1-S3 intermittently couple capacitors C21B, C22B and C23B, respectively to terminal voltages V_{T1}-V_{T4} of multi-cell battery 14, and a switch 24B provides transfer of charge to a capacitor C24B, which provides an input voltage to an LDO 42. In other embodiments, switches S1-S3 may be duplicated for switched-capacitor power circuit 40B. A separate LDO 42 is included within additional switched-capacitor power circuit 40B, but is referenced to the negative terminal of the top-most cell of multi-cell battery 14. LDO 42 supplies a second battery monitor circuit 28A with output voltage V_{SH}. LDO 42 has a power supply return also coupled to the negative terminal of the top-most cell of multi-cell battery 14, i.e., from a terminal voltage V_{T3}. In other embodiments, additional or alternative switched-capacitor power circuits may be connected to any of terminal voltages V_{T1}-V_{T4} of multi-cell battery 14, as will be described in further detail below. Example switched-capacitor battery management power supply circuit 20F may be useful when PMU 15 in example system 10 of FIG. 1 is used to monitor the condition of individual cells of multi-cell battery 14, e.g., the top-most cell, or another cell to which additional switched-capacitor power circuit 40B is coupled, providing a second output voltage V_{SH} that is referenced to that cell, for powering circuits that, for example, make measurements of the voltage across the entire multi-cell battery 14.

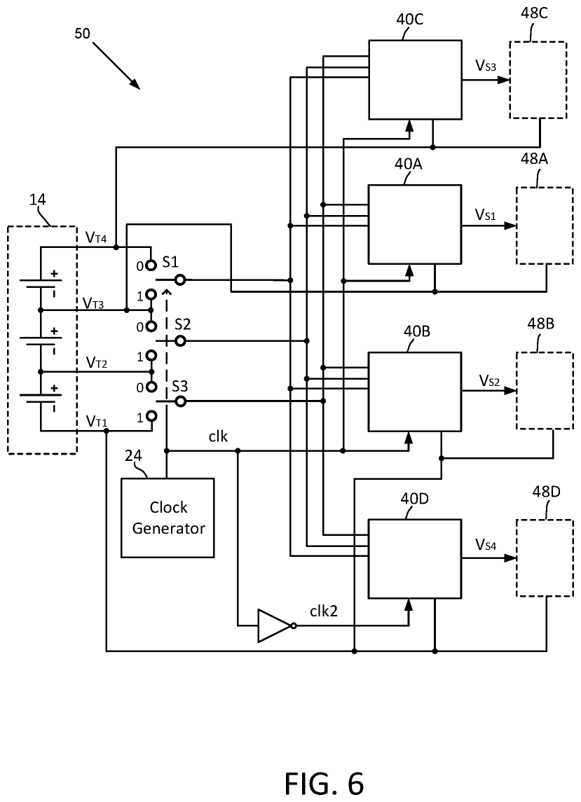

Referring now to FIG. 6, a block diagram illustrating another example system 50 is shown, in accordance with an embodiment of the disclosure. Example system 50 illustrates a generalized principle that one or more switched-capacitor power circuits 40A-40D, in the example, may be connected to the various terminal voltages V_{T1}-V_{T4} of multi-cell battery 14. Switched-capacitor power circuits 40A-40D are similar in structure and operation to example switched-capacitor battery management power supply circuit 20A of FIG. 2A, so only differences between them are described in further detail below. Switched-capacitor power circuits 40A-40D supply operating power via respective power supply voltages V_{S1}-V_{S4} supplied to corresponding battery monitors 48A-48C. By changing the polarity relationship between clock signal clk that operates switches S1-S3 and clock signal clk2 that operates the output switch (e.g., switch S4 in switched-capacitor battery management power supply circuit 20A of FIG. 2A) within switched-capacitor power circuits 40A-40D input voltages provided to internal LDOs of switched-capacitor power circuits 40A-40D may be inverted, so that LDO outputs may be provided with either polarity from any terminal of multi-cell battery 14, which provides flexibility in referencing the output voltages of switched-capacitor power circuits 40A-40D, including voltages beyond the range of terminal voltages V_{T1}-V_{T4} of multi-cell battery 14. For example, switched-capacitor power circuit 40C generates a power supply output voltage V_{S4} having an output voltage greater than that of terminal voltage V_{T4}, to which it is referenced. Switched-capacitor power circuit 40D is referenced to terminal voltage V_{T1} and generates a negative power supply having an output voltage lower than that of terminal voltage V_{T1}, to which it is referenced, while switched-capacitor power circuit 40B is also referenced to terminal voltage V_{T1}, but generates a voltage greater than terminal voltage V_{T1}. Switched-capacitor power circuit 40D generates a negative polarity due to the inversion of the input operating clock signal clk2, which is generated from clock signal clk that operates switched-capacitor power circuits 40A-40C. Switched-capacitor power circuit 40A, like switched-capacitor power circuit 40 in example switched-capacitor battery management power supply circuit 20F of FIG. 5, is referenced to negative terminal of the top-most cell of multi-cell battery 14.

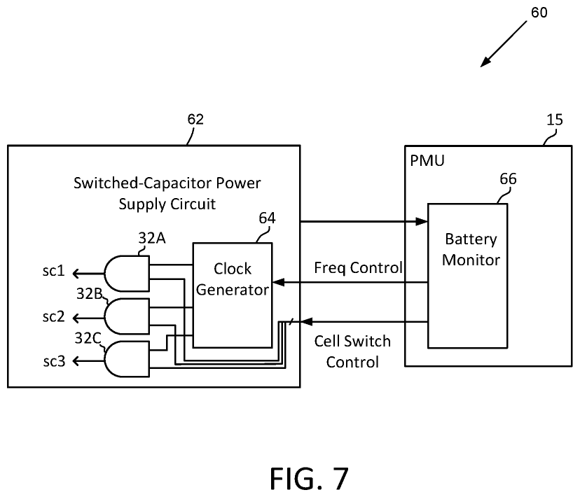

Referring now to FIG. 7, a block diagram illustrating another example system 60 is shown, in accordance with an embodiment of the disclosure. Example system 60 illustrates further controls that may be imposed on the switched-capacitor power supply circuits described above. In a switched-capacitor power supply circuit 62, which may be implemented by any of the example switched-capacitor power supply circuits 20A-20F described above, individual clock signals sc1, sc2, sc3 generated by a clock generator 64 that operates the switched-capacitor resistors, e.g., switches S1, S2 and S3 in switched-capacitor power supply 20A of FIG. 2A, may be disabled by control signals Cell Switch Control provided from a battery monitor 66 within PMU 15, which will stop the current drawn by the particular switched-capacitor resistor circuits that are disabled, permitting battery monitor 66 to further balance the energy drawn from the individual cells of multi-cell battery 14. A plurality of logical AND-gates 32A-32C are used to select which of the switched-capacitor resistor circuits are disabled/enabled. Also, example system 60 illustrates frequency control of clock generator 64 in response to a control signal(s) Freq Control, which permits battery monitor 66 to control a level of impedance of the switched capacitor resistors, either together, or individually. Since the effective resistance of the switched-capacitor elements is directly proportional to the switching frequency, varying the frequency individually permits battery monitor 66 to balance or imbalance the current drawn from the individual cells of multi-cell battery 14 to maximize the operating lifetime available from multi-cell battery 14, or by varying the frequencies together, compensate for changes in operating point, input voltage or output voltage. In one example, the most energy might be drawn from the top-most cell, or some other cell, without significant penalty, if the overall system is operable with a reduction in the total battery voltage that would occur with significant drain of the particular cell and the consequent increase of internal battery resistance of that cell.

In summary, this disclosure shows and describes circuits, methods of operation, and integrated circuits that provide power to a battery monitor that monitors a condition of a multi-cell battery. The circuit may include a switched-capacitor network having at least two capacitors and at least two corresponding first switches. The at least two capacitors may have first terminals intermittently coupled in alternation to first terminals of corresponding cells or groups of cells of the multi-cell battery and second terminals of the corresponding cells or groups of cells of the multi-cell battery by the at least two first switches according to at least one first clock signal. The switched-capacitor network may further include at least one second switch that intermittently couples second terminals of the at least two capacitors to at least one output node according to the at least one first clock signal, and the at least one output node may be configured to supply power to the battery monitor. The circuit also may include a clocking circuit for generating the at least one first clock signal.

In some example embodiments, the second terminals of the at least two capacitors may be connected to a common circuit node, and the at least one second switch may intermittently couple the common circuit node to the at least one output node. In some example embodiments, the common circuit node may be a first common circuit node, and the at least two capacitors may include at least two pairs of capacitors. The second terminals of first ones of the pairs of capacitors are connected to the first common circuit node, wherein second terminals of second ones of the pairs of capacitors may be connected to a second common circuit node, and the at least one second switch may include at least one pair of second switches that intermittently couple corresponding ones of the first common circuit node and the second common circuit node to the at least one output node in different phases of the at least one first clock signal. In some example embodiments, the at least one second switch may include at least two second switches corresponding to the at least two capacitors, and the at least two second switches may intermittently couple the second terminals of the at least two capacitors to the at least one output node in different phases of the first clock signal. In some example embodiments, the at least two capacitors may have different voltage ratings selected to meet or exceed a rated voltage of their corresponding first terminals of the cells or groups of cells with respect to a return voltage associated with the at least one output node.

In some example embodiments, the at least two capacitors may have equal capacitance values. In some example embodiments, the circuit may include a low drop-out regulator having an input coupled to the output node and an output coupled to the battery monitor. In some example embodiments, the low drop-out regulator may be a first low drop-out regulator, and the circuit may further include a second low drop-out regulator having an input coupled to a top-most cell of the multi-cell battery for providing a secondary source of power to the battery monitor. In some example embodiments, the second low drop-out regulator may an output coupled to an input of the first low drop-out regulator. In some example embodiments, outputs of the first low drop-out-regulator and the second low drop-out regulator may be coupled in parallel to the battery monitor. In other example embodiments, the low drop-out regulator may be a first low drop-out regulator referenced to a top-most cell of the multi-cell battery and the circuit may further include a second low drop-out regulator having an output coupled to the battery monitor and referenced to a bottom-most cell of the multi-cell battery.

In some example embodiments, the at least one clock signal may include at least two clock signals provided to corresponding ones of the at least two first switches, and the clocking circuit may have at least one input for controlling frequencies of the at least two clock signals. In some example embodiments, the circuit may further include a control circuit having an output coupled to the at least one input of the clock generator that varies one or more values provided to the input of the clock generator in order to increase a run time available from the battery by varying the frequencies of the at least two clock signals. In some example embodiments, the at least one clock signal may include at least two clock signals provided to corresponding ones of the at least two first switches. In some example embodiments, the clocking circuit may selectively disable one or more of the at least two clock signals to selectively interrupt energy drain from an associated one of the multiple cells or groups of cells.

While the disclosure has shown and described particular embodiments of the techniques disclosed herein, it will be understood by those skilled in the art that the foregoing and other changes in form, and details may be made therein without departing from the spirit and scope of the disclosure. For example, the techniques shown above may be applied to supplying power to a circuit other than a battery management IC.

1. A circuit for providing power to a battery monitor that monitors a condition of a multi-cell battery, the circuit comprising:
a switched-capacitor network including at least two capacitors and at least two corresponding first switches, wherein the at least two capacitors have first terminals intermittently coupled in alternation to first terminals of corresponding cells or groups of cells of the multi-cell battery and second terminals of the corresponding cells or groups of cells of the multi-cell battery by the at least two first switches according to at least one first clock signal, and wherein the switched-capacitor network further comprises at least one second switch that intermittently couples second terminals of the at least two capacitors to at least one output node according to the at least one first clock signal, wherein the at least one output node is configured to supply power to the battery monitor; and
a clocking circuit for generating the at least one first clock signal.

2. The circuit of claim 1, wherein the second terminals of the at least two capacitors are connected to a common circuit node, and wherein the at least one second switch intermittently couples the common circuit node to the at least one output node.

3. The circuit of claim 2, wherein the common circuit node is a first common circuit node, wherein the at least two capacitors comprises at least two pairs of capacitors, wherein the second terminals of first ones of the pairs of capacitors are connected to the first common circuit node, wherein second terminals of second ones of the pairs of capacitors are connected to a second common circuit node, and wherein the at least one second switch comprises at least one pair of second switches that intermittently couple corresponding ones of the first common circuit node and the second common circuit node to the at least one output node in different phases of the at least one first clock signal.

4. The circuit of claim 1, wherein the at least one second switch comprises at least two second switches corresponding to the at least two capacitors, and wherein the at least two second switches intermittently couple the second terminals of the at least two capacitors to the at least one output node in different phases of the first clock signal.

5. The circuit of claim 1, wherein the at least two capacitors have different voltage ratings selected to meet or exceed a rated voltage of their corresponding first terminals of the cells or groups of cells with respect to a return voltage associated with the at least one output node.

6. The circuit of claim 1, wherein the at least two capacitors have equal capacitance values.

7. The circuit of claim 1, further comprising a low drop-out regulator having an input coupled to the output node and an output coupled to the battery monitor.

8. The circuit of claim 7, wherein the low drop-out regulator is a first low drop-out regulator, and further comprising a second low drop-out regulator having an input coupled to a top-most cell of the multi-cell battery for providing a secondary source of power to the battery monitor.

9. The circuit of claim 8, wherein the second low drop-out regulator has an output coupled to an input of the first low drop-out regulator.

10. The circuit of claim 8, wherein outputs of the first low drop-out-regulator and the second low drop-out regulator are coupled in parallel to the battery monitor.

11. The circuit of claim 7, wherein the low drop-out regulator is a first low drop-out regulator referenced to a top-most cell of the multi-cell battery and further comprising a second low drop-out regulator having an output coupled to the battery monitor and referenced to a bottom-most cell of the multi-cell battery.

12. The circuit of claim 1, wherein the at least one clock signal comprises at least two clock signals provided to corresponding ones of the at least two first switches, wherein the clocking circuit has at least one input for controlling frequencies of the at least two clock signals, and further comprising a control circuit having an output coupled to the at least one input of the clock generator that varies one or more values provided to the input of the clock generator in order to increase a run time available from the battery by varying the frequencies of the at least two clock signals.

13. The circuit of claim 1, wherein the at least one clock signal comprises at least two clock signals provided to corresponding ones of the at least two first switches, wherein the clocking circuit selectively disables one or more of the at least two clock signals to selectively interrupt energy drain from an associated one of the multiple cells or groups of cells.

14. A method of providing power to a battery monitor that monitors a condition of a multi-cell battery, the method comprising:
first intermittently coupling first terminals of the at least two capacitors in alternation between first terminals of corresponding cells or groups of cells of the multi-cell battery and second terminals of the corresponding cells or groups of cells of the multi-cell battery by at least two first switches of a switched-capacitor network, according to at least one first clock signal;
second intermittently coupling second terminals of the at least two capacitors to at least one output node by at least one second switch, according to the at least one first clock signal; and
supplying power to the battery monitor from the at least one output node.

15. The method of claim 14, wherein the second terminals of the at least two capacitors are connected to a common circuit node, and wherein second intermittently coupling intermittently couples the common circuit node to the at least one output node.

16. The method of claim 15, wherein the common circuit node is a first common circuit node, wherein the at least two capacitors comprises at least two pairs of capacitors, wherein the second terminals of first ones of the pairs of capacitors are connected to the first common circuit node, wherein second terminals of second ones of the pairs of capacitors are connected to a second common circuit node, wherein the at least one second switch comprises at least one pair of second switches, and wherein the second intermittently coupling intermittently couples corresponding ones of the first common circuit node and the second common circuit node to the at least one output node in different phases of the at least one first clock signal.

17. The method of claim 14, wherein the at least one second switch comprises at least two second switches corresponding to the at least two capacitors, and wherein the second intermittently coupling intermittently couples the second terminals of the at least two capacitors to the at least one output node in different phases of the first clock signal.

18. The method of claim 14, wherein the at least two capacitors have different voltage ratings selected to meet or exceed a rated voltage of their corresponding first terminals of the cells or groups of cells with respect to a return voltage associated with the at least one output node.

19. The method of claim 14, wherein the at least two capacitors have equal capacitance values.

20. The method of claim 14, further comprising generating an output voltage provided to the battery monitor with a low drop-out regulator having an input coupled to the output node.

21. The method of claim 20, wherein the low drop-out regulator is a first low drop-out regulator, and further comprising providing a secondary source of power to the battery monitor from a second low drop-out regulator having an input coupled to a top-most cell of the multi-cell battery.

22. The method of claim 21, further comprising coupling an output of the second low drop-out regulator to an input of the first low drop-out regulator.

23. The method of claim 21, further comprising coupling outputs of the first low drop-out-regulator and the second low drop-out regulator in parallel to provide energy to the battery monitor.

24. The method of claim 21, wherein the low drop-out regulator is a first low drop-out regulator referenced to a top-most cell of the multi-cell battery and further comprising providing a second low drop-out regulator having an output coupled to the battery monitor and referenced to a bottom-most cell of the multi-cell battery.

25. The method of claim 14, wherein the at least one clock signal comprises at least two clock signals provided to corresponding ones of the at least two first switches, and wherein the method further comprises varying the frequencies of the at least two clock signals in order to increase a run time available from the battery.

26. The method of claim 14, wherein the at least one clock signal comprises at least two clock signals provided to corresponding ones of the at least two first switches, and wherein the method further comprises selectively disabling one or more of the at least two clock signals to selectively interrupt energy drain from an associated one of the multiple cells or groups of cells.
